(19) United States
(12) Patent Application Publication
(10) Pub. No.: US 2024/0423019 A1
(43) Pub. Date: Dec. 19, 2024

(54) DISPLAY DEVICE AND METHOD OF MANUFACTURING THE DISPLAY DEVICE

(71) Applicant: Samsung Display Co., LTD., Yongin-si (KR)

(72) Inventor: Dong Ha LEE, Yongin-si (KR)

(73) Assignee: Samsung Display Co., LTD., Yongin-si (KR)

(21) Appl. No.: 18/434,871

(22) Filed: Feb. 7, 2024

(30) Foreign Application Priority Data
Jun. 14, 2023 (KR) 10-2023-0076251

(51) Int. Cl. H10K 59/12; H10K 50/13; H10K 59/122

(52) U.S. Cl. CPC H10K 59/1201; H10K 50/13; H10K 59/122

(57) ABSTRACT

A display device includes a bank including an opening overlapping an emission area, and a light emitting clement layer disposed on the bank. The light emitting element layer includes a first area and a second area. The first and second areas of the light emitting element layer are separated from each other in the opening. A thickness of the first area is different from a thickness of the second area.

### CROSS-REFERENCE TO RELATED APPLICATION

This application claims priority to and benefits of Korean patent application No. 10-2023-0076251 under 35 U.S.C. § 119, filed on Jun. 14, 2023 in the Korean Intellectual Property Office (KIPO), the entire disclosure of which is incorporated herein by reference.

### BACKGROUND

### 1. Technical Field

The disclosure generally relates to a display device and a method of manufacturing the display device.

### 2. Related Art

Recently, as interest in information displays is increased, research and development of display devices have been continuously conducted.

### SUMMARY

Embodiments provide a display device and a method of manufacturing the display device, which can improve the luminance uniformity of the display device.

The technical objectives to be achieved by the disclosure are not limited to those described herein, and other technical objectives that are not mentioned herein would be clearly understood by a person skilled in the art from the description of the disclosure.

In accordance with an aspect of the disclosure, there is provided a display device including a bank including an opening overlapping an emission area; and a light emitting element layer disposed on the bank. The light emitting element layer includes a first area and a second area, the first and second areas of the light emitting element layer are separated from each other in the opening, and a thickness of the first area is different from a thickness of the second area.

The second area may surround the first area.

The first area may be disposed in a middle of the opening.

The second area may be in contact with the bank.

The first area may have uniform thicknesses.

The second area may have non-uniform thicknesses.

The light emitting element layer may include a first layer disposed on the bank and a second layer disposed on the first layer. A thermal expansion coefficient of the first layer may be different from a thermal expansion coefficient of the second layer.

The second layer may be disposed directly on the first layer.

The light emitting element layer may further include a third layer disposed on the second layer. A thermal expansion coefficient of the third layer may be different from the thermal expansion coefficient of the second layer.

The third layer may be disposed directly on the second layer.

In accordance with another aspect of the disclosure, there is provided a method of manufacturing a display device, the method including forming a bank including an opening over a first electrode; forming a light emitting element layer in the opening; forming a crack in the light emitting element layer by baking the light emitting element layer; and forming a second electrode on the light emitting element layer.

The light emitting element layer may include a first area and a second area, which have different thicknesses from each other.

The crack may separate the first area and the second area from each other.

The first area may have uniform thicknesses.

The first area may be formed in a middle of the opening.

The second area may have non-uniform thicknesses.

The second area may surround the first area.

The forming of the light emitting element layer may include forming a first layer on the first electrode and forming a second layer on the first layer.

A thermal expansion coefficient of the first layer may be different from a thermal expansion coefficient of the second layer.

The forming of the light emitting element layer may further include forming a third layer on the second layer. A thermal expansion coefficient of the third layer may be different from the thermal expansion coefficient of the second layer.

In accordance with the disclosure, adjacent layers of a light emitting element layer are formed of materials having different thermal expansion coefficients, thereby forming a crack inside the light emitting element layer. Thus, a current in an area in which the thickness of the light emitting element layer is non-uniform is blocked, thereby improving luminance uniformity.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic perspective view illustrating a display device in accordance with an embodiment of the disclosure.

FIG. 2 is a schematic sectional view illustrating a display device in accordance with an embodiment of the disclosure.

FIG. 3 is a schematic plan view illustrating a display panel in accordance with an embodiment of the disclosure.

FIG. 4 is a schematic sectional view illustrating a display panel in accordance with an embodiment of the disclosure.

FIGS. 5 and 6 are schematic sectional views illustrating a display element layer shown in FIG. 4.

FIGS. 7 to 10 are schematic sectional views illustrating process steps of a method of manufacturing a display device in accordance with an embodiment of the disclosure.

### DETAILED DESCRIPTION OF THE EMBODIMENTS

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms. The embodiments are provided by way of example only so that a person of ordinary skilled in the art can understand the features in the disclosure and the scope thereof. Therefore, the disclosure can be defined by the scope of the appended claims.

The terminology used herein is for the purpose of describing particular embodiments only and is not construed as limiting the inventive concept. As used herein, the singular forms are intended to include the plural forms as well, unless the context clearly indicates otherwise. The terms “comprises/includes” and/or “comprising/including,” when used in this specification, specify the presence of mentioned component, step, operation and/or element, but do not exclude the presence or addition of one or more other components, steps, operations and/or elements.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

The term “on” that is used to designate that an element or layer is on another element or layer includes both a case where an element or layer is located directly on another element or layer, and a case where an element or layer is located on another element or layer via still another element layer. Like reference numerals generally denote like elements throughout the specification.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in more detail with reference to the accompanying drawings.

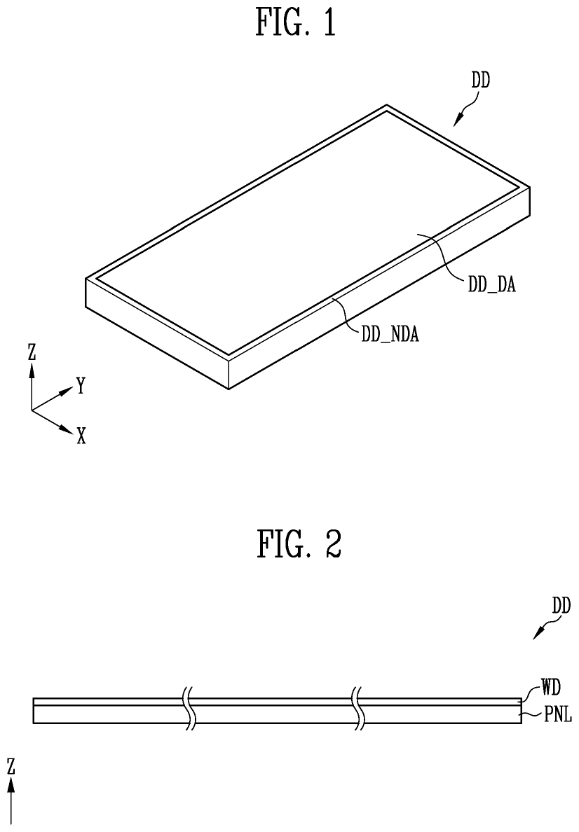

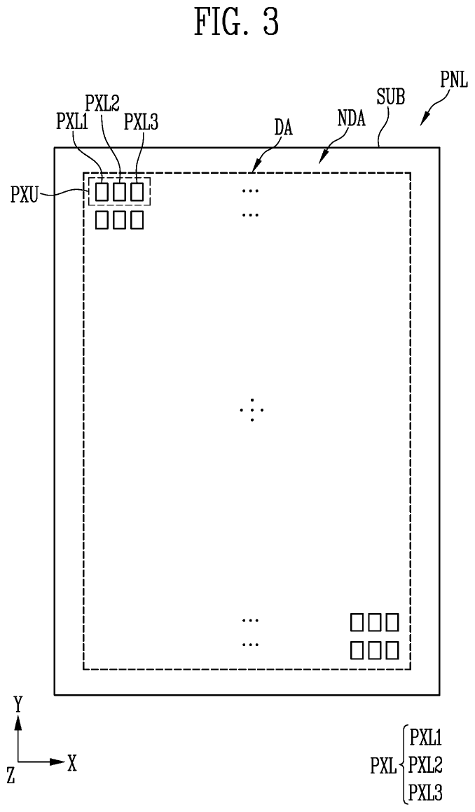

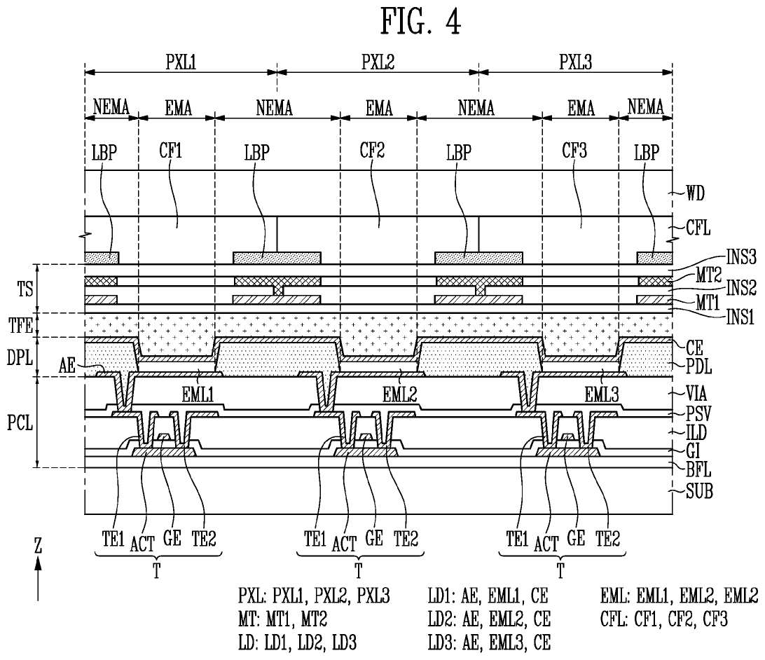

FIG. 1 is a schematic perspective view illustrating a display device in accordance with an embodiment of the disclosure. FIG. 2 is a schematic sectional view illustrating a display device in accordance with an embodiment of the disclosure. FIG. 3 is a schematic plan view illustrating a display panel in accordance with an embodiment of the disclosure.

Referring to FIGS. 1 to 3, the display device DD may include a display panel PNL and a window WD.

The display device DD may include a display area DD_DA in which an image is displayed and a non-display area DD_NDA in which the image is not displayed. The non-display area DD_NDA may be provided at at least one side of the display area DD_DA. In an example, the non-display area DD_NDA may be adjacent to or surround the display area DD_DA.

The display device DD may be provided in a rectangular plate shape having angular corners. However, in some embodiments, the corners of the display device DD may have a curved shape. However, the disclosure is not necessarily limited thereto, and the display device DD may be implemented in various shapes.

The display device DD may be applied to an electronic device in which a display surface is applied to at least one surface thereof, such as a smartphone, a television, a tablet personal computer (PC), a mobile phone, a video phone, an electronic book reader, a desktop PC, a laptop PC, a netbook computer, a workstation, a server, a personal digital assistant (PDA), a portable multimedia player (PMP), an MP3 player, a medical device, a camera, or a wearable device.

The display panel PNL and a substrate SUB for forming the same may include a display area DA for displaying an image and a non-display area NDA except the display area DA. The display area DA may constitute a screen on which the image is displayed, and the non-display area NDA may be the other area except the display area DA.

For convenience of discussion, in FIG. 3, a structure of the display panel PNL will be briefly illustrated based on the display area DA. However, in some embodiments, at least one driving circuit (e.g., at least one of a scan driver and a data driver), lines, and/or pads may be further disposed in the display panel PNL.

A pixel unit PXU may be disposed in the display area DA. The pixel unit PXU may include a first pixel PXL1, a second pixel PXL2, and/or a third pixel PXL3. Hereinafter, in case that at least one pixel among the first pixel PXL1, the second pixel PXL2, and the third pixel PXL3 is arbitrarily designated or in case that two or more kinds of pixels among the first pixel PXL1, the second pixel PXL2, and the third pixel PXL3 are inclusively designated, the corresponding pixel or the corresponding pixels will be referred to as a “pixel PXL” or “pixels PXL.”

The pixels PXL may be regularly arranged according to a stripe structure, a PENTILE™ structure, or the like. However, the arrangement structure of the pixels PXL is not limited thereto, and the pixels PXL may be arranged in the display area DA by using various structures and/or methods.

In some embodiments, two or more of pixels PXL emit lights of different colors. In an example, first pixels PXL1 emitting light of a first color, second pixels PXL2 emitting light of a second color, and third pixels PXL3 emitting light of a third color may be arranged in the display area DA. At least one first pixel PXL1, at least one second pixel PXL2, and at least one third pixel PXL3, which are disposed adjacent to each other, may constitute one pixel unit PXU capable of emitting lights of various colors. For example, the first pixel PXL1 may be a red pixel emitting light of red, the second pixel PXL2 may be a green pixel emitting light of green, and the third pixel PXL3 may be a blue pixel emitting light of blue. However, the disclosure is not limited thereto. Although a case where the pixel unit PXU includes one first pixel PXL1, one second pixel PXL2, and one third pixel PXL3 is shown as an example in FIG. 3, the disclosure is not necessarily limited thereto. The pixel unit PXU may include one first pixel PXL1, two second pixels PXL2, and one third pixel PXL3.

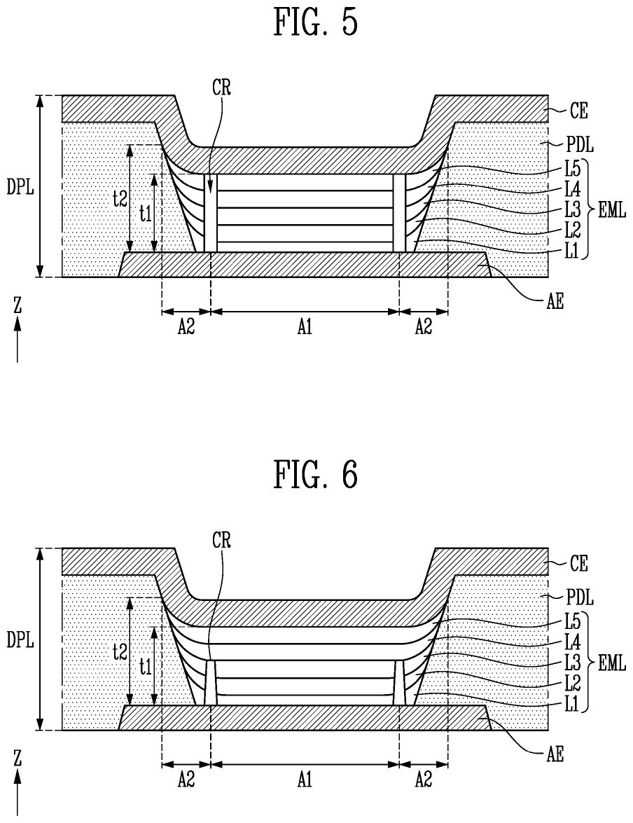

The first pixel PXL1, the second pixel PXL2, and the third pixel PXL3 may have, as light sources, a first light emitting element (LD1 shown in FIG. 4), a second light emitting clement (LD2 shown in FIG. 4), and a third light emitting element (LD3 shown in FIG. 4), to emit light of a first color, light of a second color, and light of a third color, respectively. However, the color of light emitted from each pixel PXL may be variously changed.

The window WD for protecting an exposed surface of the display panel PNL may be provided on the display panel PNL. The window WD may protect the display panel PNL from external impact, and provide an input surface and/or a display surface to a user. The window WD may be bonded to the display panel PNL by using an optical clear adhesive (or cohesive) member (not shown).

The window WD may have a multi-layer structure selected from a glass substrate, a plastic film, and a plastic substrate. The multi-layer structure may be formed through a continuous process or an adhesion process using an adhesive layer. The whole or a portion of the window WD may have flexibility.

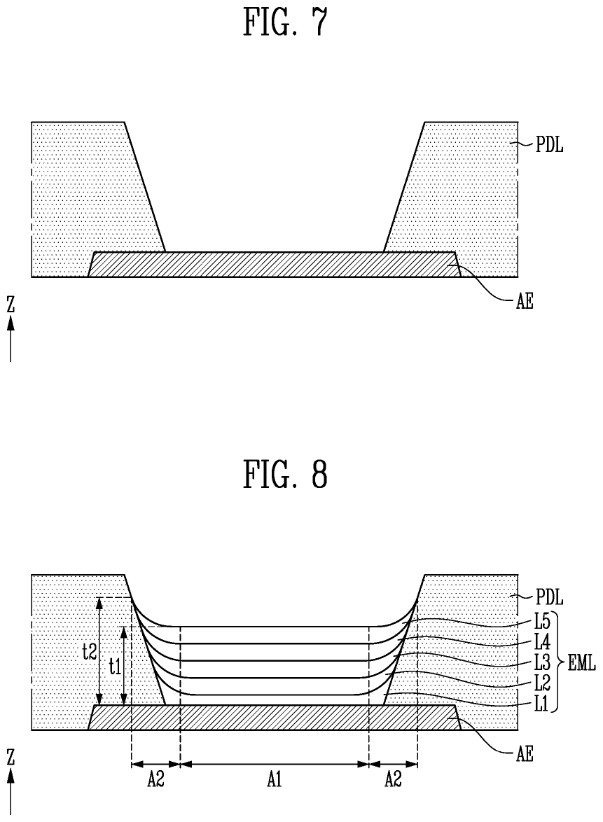

FIG. 4 is a schematic sectional view illustrating a display panel in accordance with an embodiment of the disclosure. FIGS. 5 and 6 are schematic sectional views illustrating a display element layer shown in FIG. 4.

Referring to FIG. 4, each of first to third pixels PXL1, PXL2, and PXL3 may include an emission area EMA, and a non-emission area NEMA may be located between the emission areas EMA of the first to third pixels PXL1, PXL2, and PXL3.

Each of the first to third pixels PXL1, PXL2, and PXL3 may include a pixel circuit layer PCL, a display clement layer DPL, and a thin film encapsulation layer TFE, which are sequentially disposed on a substrate SUB.

The substrate SUB may form a base surface. The substrate SUB may include a transparent insulating material to allow light to be transmitted therethrough. The substrate SUB may be a rigid substrate or a flexible substrate. The rigid substrate may be, for example, at least one of a glass substrate, a quartz substrate, a glass ceramic substrate, and a crystalline glass substrate. The flexible substrate may be at least one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the disclosure is not limited thereto.

The pixel circuit layer PCL may include a pixel circuit provided on the substrate SUB. The pixel circuit layer PCL may include a sensor circuit provided on the substrate SUB.

The pixel circuit layer PCL may include a buffer layer BFL, a gate insulating layer GI, an interlayer insulating layer ILD, a passivation layer PSV, and/or a via layer VIA, which are sequentially stacked on the substrate SUB along a third direction (Z-axis direction).

The buffer layer BFL may be an inorganic insulating layer including an inorganic material. The buffer layer BFL may include, e.g., at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer, but be provided as a multi-layer including at least two layers. In case that the buffer layer BFL is provided as the multi-layer, the layers may be formed of the same material or be formed of different materials. The buffer layer BFL may be omitted according to a material of the substrate SUB, a process condition, or the like.

A transistor T may be disposed on the buffer layer BFL. The transistor T may include an active pattern ACT, a gate electrode GE, a first transistor electrode TE1, and/or a second transistor electrode TE2.

The active pattern ACT may be disposed on the buffer layer BFL. The active pattern ACT may include a poly-silicon semiconductor. For example, the active pattern ACT may be formed through a low temperature poly-silicon process. However, the disclosure is not necessarily limited thereto, and the active pattern ACT may be formed of an oxide semiconductor, a metal oxide semiconductor, or the like.

Each active pattern ACT may include a channel region, a first contact region connected to one end of the channel region, and/or a second contact region connected to another end of the channel region. The channel region, the first contact region, and the second contact region may be formed of a semiconductor layer undoped or doped with an impurity. In an example, the first contact region and the second contact region may be formed of a semiconductor layer doped with the impurity, and the channel region may be formed of a semiconductor layer undoped with the impurity. The impurity may include a p-type impurity, but the disclosure is not limited thereto. One of the first and second contact regions may be a source region, and the other of the first and second contact regions may be a drain region.

The gate insulating layer GI may be disposed over (or on) the active pattern ACT. The gate insulating layer GI may be an inorganic layer (or inorganic insulating layer) including an inorganic material. In an example, the gate insulating layer GI may include at least one of silicon nitride (SiNₓ), silicon oxide (SiOₓ), silicon oxynitride (SiOₓN_{y}), and a metal oxide such as aluminum oxide (AlOₓ). However, the material of the gate insulating layer GI is not limited to the above-described embodiments. In some embodiments, the gate insulating layer GI may be an organic layer (or organic insulating layer) including an organic material. The gate insulating layer GI may be provided as a single layer, but be provided as a multi-layer including at least two layers.

The gate electrode GE may be disposed on the gate insulating layer GI. The gate electrode GE may overlap the channel region of the active pattern ACT. The gate electrode GE may be formed as a single layer including one selected from the group consisting of copper (Cu), molybdenum (Mo), tungsten (W), aluminum neodymium (AlNd), titanium (Ti), aluminum (Al), silver (Ag), and any alloy thereof or a mixture thereof, or be formed in a double-or multi-layer structure including molybdenum (Mo), titanium (Ti), copper (Cu), aluminum (Al) or silver (Ag), which is a low-resistance material so as to decrease wiring resistance.

The interlayer insulating layer ILD may be disposed over the gate electrode GE. The interlayer insulating layer ILD and the gate insulating layer GI may include a same material. In the alternative, the interlayer insulating layer ILD may include at least one material selected from, e.g., the materials discussed herein with respect to the material constituting the gate insulating layer GI.

The first transistor electrode TE1 and the second transistor electrode TE2 may be disposed on the interlayer insulating layer ILD.

The first transistor electrode TE1 of the transistor T may be in contact with the first contact region of the active pattern ACT through a contact hole penetrating the interlayer insulating layer ILD and the gate insulating layer GI. In case that the first contact region is the source region, the first transistor electrode TE1 may be a first source electrode.

The second transistor electrode TE2 of the transistor T may contact or may be in contact with the second contact region of the active pattern ACT through a contact hole penetrating the interlayer insulating layer ILD and the gate insulating layer GI. In case that the first contact region is the drain region, the first transistor electrode TE1 may be a second drain electrode.

Each of the first transistor electrode TE1 and the second transistor electrode TE2 and the gate electrode GE may include a same material. In the alternative, each of the first transistor electrode TE1 and the second transistor electrode TE2 may include at least one material selected from, e.g., the materials discussed herein with respect to the material constituting the gate electrode GE.

The passivation layer PSV may be disposed over the first transistor electrode TE1 and the second transistor electrode TE2. The passivation layer PSV (e.g., a protective layer) may be an inorganic layer (or inorganic insulating layer) including an inorganic material or an organic layer (or organic insulating layer) including an organic material. The inorganic layer may include, for example, at least one of silicon oxide (SiOx), silicon nitride (SiNx), silicon oxynitride (SiOxNy), and a metal oxide such as aluminum oxide (AlOx). The organic layer may include, for example, at least one of acrylic resin, epoxy resin, phenolic resin, polyamide resin, polyimide resin, unsaturated polyester resin, polyphenylene ether resin, polyphenylene sulfide resin, and benzocyclobutene resin.

In some embodiments, the passivation layer PSV and the interlayer insulating layer may include a same material, but the disclosure is not limited thereto. The passivation layer PSV may be provided as a single layer, but be provided as a multi-layer including at least two layers.

The via layer VIA may be disposed on the passivation layer PSV. The via layer VIA and the passivation layer PSV may include a same material. In the alternative, the via layer VIA may include at least one material selected from, e.g., the materials discussed herein with respect to the material constituting the passivation layer PSV.

The display element layer DPL may be disposed on the pixel circuit layer PCL.

The display element layer DPL may include a light emitting element LD emitting light. The first to third pixels PXL1, PXL2, and PXL3 may include first to third light emitting elements LD1, LD2, and LD3, respectively.

The first light emitting element LD1 may include a first electrode AE, a first light emitting element layer EML1, and a second electrode CE. The second light emitting element LD2 may include a first electrode AE, a second light emitting element layer EML2, and a second electrode CE. The third light emitting element LD3 may include a first electrode AE, a third light emitting element layer EML3, and a second electrode CE. In an example, each of the first to third light emitting elements LD1, LD2, and LD3 may be a top-emission organic light emitting element.

A first electrode AE of each pixel PXL may be disposed in the emission area EMA, and first electrodes AE of pixels PXL may be spaced apart from each other. The first electrode AE of each pixel PXL may be electrically connected to a first transistor electrode TE1 of a transistor T of the corresponding pixel PXL.

A bank PDL may be disposed over the first electrode AE. The bank PDL may define (or partition) the emission area EMA of each pixel PXL. The bank PDL may include an opening partially exposing the first electrode AE of each pixel PXL. The opening of the bank PDL may overlap the emission area EMA of each pixel PXL.

The bank PDL may be an organic insulating layer made of an organic material. The organic material may include, e.g., at least one of acrylic resin, epoxy resin, phenolic resin, polyamide resin, polyimide resin, and the like.

In some embodiments, the bank PDL may include a light absorption material, or have a light absorber applied thereon, to absorb light introduced from the outside. For example, the bank PDL may include a carbon-based black pigment. However, the disclosure is not necessarily limited thereto, and the bank PDL may include an opaque metal material such as chromium (Cr), molybdenum (Mo), an alloy (MoTi) of molybdenum and titanium, tungsten (W), vanadium (V), niobium (Nb), tantalum (Ta), manganese (Mn), cobalt (Co) or nickel (Ni), which has a high light absorption rate.

A light emitting element layer EML of each pixel PXL may be disposed on the first electrode AE exposed by the bank PDL. The light emitting element layer EML will be described in detail with reference to FIGS. 5 and 6.

Referring to FIGS. 5 and 6, the light emitting element layer EML may be disposed in the opening of the bank PDL. The light emitting element layer EML may include a first area A1 and a second area A2, which are separated from each other in the opening of the bank PDL. The first area A1 of the light emitting element layer EML may be disposed in the middle of the opening of the bank PDL. In an example, the first area A1 of the light emitting clement layer EML may be an area in which a thickness of the light emitting element layer EML is uniform or the light emitting element layer EML has uniform thicknesses.

The second area A2 of the light emitting element layer EML may surround the first area A1. The second area A2 of the light emitting element layer EML may be disposed at en edge of the opening of the bank PDL to be in contact with the bank PDL. In an example, the second area A2 of the light emitting element layer EML may be an area in which a thickness of the light emitting element layer EML is non-uniform or the light emitting element layer EML has non-uniform thicknesses. In an embodiment, a thickness t2 of the second area A2 of the light emitting element layer EML may be different from a thickness t1 of the first area A1 of the light emitting element layer EML. The thickness t2 of the second area A2 of the light emitting clement layer EML may be thicker (or greater) than the thickness t1 of the first area A1 of the light emitting element layer EML, but the disclosure is not necessarily limited thereto.

As described above, in case that the thickness t2 of the second area A2 of the light emitting element layer EML is non-uniformly formed, the light emitting element layer EML may non-uniformly emit light in the second area A2. Thus, as the first area A1 of the light emitting element layer EML is separated from the second area A2 of the light emitting clement layer EML, a current in the second area A2 is blocked, thereby improving luminance uniformity. In an example, the first area A1 and the second area A2 of the light emitting element layer EML may be separated from each other by a crack CR.

As shown in FIG. 5, the crack CR may entirely separate the first area A1 and the second area A2 of the light emitting element layer EML from each other. In an example, in case that the light emitting element layer EML includes first to fifth layers L1, L2, L3, L4, and L5 sequentially stacked therein, the crack CR may be formed in all the first to fifth layers L1, L2, L3, L4, and L5 to entirely separate the first area A1 and the second area A2 of the first to fifth layers L1, L2, L3, L4, and L5 from each other.

As shown in FIG. 6, the crack CR may partially separate the first area A1 and the second area A2 of the light emitting element layer EML from each other. In an example, in case that the light emitting element layer EML includes first to fifth layers L1, L2, L3, L4, and L5 sequentially stacked therein, the crack CR may be formed in some of the first to fifth layers L1, L2, L3, L4, and L5 to partially separate the first area A1 and the second area A2 of the first to fifth layers L1, L2, L3, L4, and L5 from each other. Although a case where a crack CR is partially formed in the first to third layers L1, L2, and L3 is shown as an example in FIG. 6, the disclosure is not necessarily limited thereto.

The first layer L1 may be disposed on the first electrode AE and the bank PDL. The first layer L1 may be disposed directly on the first electrode AE and the bank PDL. In an example, the first layer L1 may be a hole injection layer, but the disclosure is not necessarily limited thereto.

The second layer L2 may be disposed on the first layer L1. The second layer L2 may be disposed directly on the first layer L1. In an example, the second layer L2 may be a hole transport layer, but the disclosure is not necessarily limited thereto. In an embodiment, a thermal expansion coefficient of the second layer L2 may be different from a thermal expansion coefficient of the first layer L1. As such, in case that adjacent layers of the light emitting element layer EML are formed of materials having different thermal expansion coefficients, a crack CR may be formed inside the light emitting element layer EML due to thermal expansion in case that baking is performed at a high temperature. The crack CR of the light emitting element layer EML may be formed between the first area A1 and the second area A2 to block a current in the second area A2, thereby improving the luminance uniformity.

The third layer L3 may be disposed on the second layer L2. The third layer L3 may be disposed directly on the second layer L2. In an embodiment, a thermal expansion coefficient of the third layer L3 may be different from the thermal expansion coefficient of the second layer L2. In an example, the third layer L3 may be a light emitting layer, but the disclosure is not necessarily limited thereto.

The fourth layer L4 may be disposed on the third layer L3. The fourth layer L4 may be disposed directly on the third layer L3. In an embodiment, a thermal expansion coefficient of the fourth layer L4 may be different from the thermal expansion coefficient of the third layer L3. In an example, the fourth layer L4 may be an electron transport layer, but the disclosure is not necessarily limited thereto.

The fifth layer L5 may be disposed on the fourth layer L4. The fifth layer L5 may be disposed directly on the fourth layer L4. In an embodiment, a thermal expansion coefficient of the fifth layer L5 may be different from the thermal expansion coefficient of the fourth layer L4. In an example, the fifth layer L5 may be an electron injection layer, but the disclosure is not necessarily limited thereto.

Although a case where the light emitting element layer EML includes the first to fifth layers L1, L2, L3, L4, and L5 is shown as an example in FIGS. 5 and 6, the disclosure is not necessarily limited thereto. In an example, the light emitting element layer EML may additionally include layers include an electron blocking layer and/or a hole blocking layer.

The second electrode CE may be disposed on the light emitting element layer EML. The second electrode CE may be disposed throughout all the first to third pixels PXL1, PXL2, and PXL3. In an example, the second electrode CE may be provided as a common electrode, but the disclosure is not necessarily limited thereto.

The second electrode CE may be configured with a metal layer such as silver (Ag), magnesium (Mg), aluminum (Al), platinum (Pt), palladium (Pd), gold (Au), nickel (Ni), neodymium (Nd), iridium (Ir), chromium (Cr) or any alloy thereof, and/or a transparent conductive layer such as indium tin oxide (ITO), indium zinc oxide (IZO), zinc oxide (ZnO) or indium tin zinc oxide (ITZO). In some embodiments, the second electrode CE may be configured as a multi-layer including at least two layers including a metal thin layer. For example, the second electrode CE may be configured as a triple layer of ITO/Ag/ITO.

The thin film encapsulation layer TFE may be disposed on the display element layer DPL. The thin film encapsulation layer TFE may have a single-layer structure or a multi-layer structure. The thin film encapsulation layer TFE may include insulating layers covering the light emitting element LD. The thin film encapsulation layer TFE may include at least one of an inorganic layer and an organic layer. For example, the thin film encapsulation layer TFE may include at least one inorganic layer and at least one organic layer. For example, the thin film encapsulation layer TFE may have a structure in which an inorganic layer and an organic layer are alternately stacked. In some embodiments, the thin film encapsulation layer TFE may be an encapsulation substrate disposed over the light emitting element LD to be bonded to the substrate SUB through a sealant.

A sensing layer TS may be disposed on the thin film encapsulation layer TFE. The sensing layer TS may include a first insulating layer INS1, a first sensing conductive layer MT1, a second insulating layer INS2, a second sensing conductive layer MT2, and/or a third insulating layer INS3.

The first insulating layer INS1 may be an inorganic insulating layer including an inorganic material or an organic insulating layer including an organic material. The inorganic insulating layer may include an inorganic insulating material such as silicon oxide (SiOₓ), silicon nitride (SiNₓ), silicon oxynitride (SiOₓN_{y}), aluminum oxide (AlOₓ), titanium oxide (TiOₓ), tantalum oxide (TaₓO_{y}), hafnium oxide (HfOₓ), or zinc oxide (ZnOₓ). The organic insulating layer may include at least one of acryl-based resin, methacryl-based resin, polyisoprene, vinyl-based resin, epoxy-based resin, urethane-based resin, cellulose-based resin, siloxane-based resin, polyimide-based resin, polyamide-based resin, and perylene-based resin. However, the disclosure is not necessarily limited thereto. The first insulating layer INS1 may be omitted in some embodiments, or be configured as an uppermost layer of the thin film encapsulation layer.

The first sensing conductive layer MT1 may be disposed on the first insulating layer INS1. The first sensing conductive layer MT1 may be partially opened not to overlap the light emitting element LD of each pixel PX. In an example, the first sensing conductive layer MT1 may be disposed to overlap the non-emission area NEMA at the periphery of the emission area EMA.

The first sensing conductive layer MT1 may include a metal layer or a transparent conductive layer. For example, the metal layer may include at least one of molybdenum, titanium, copper, aluminum, and alloys thereof. The transparent conductive layer may include, e.g., at least one of indium tin oxide (ITO), indium zinc oxide (IZO), zinc oxide (ZnO), indium tin zinc oxide (ITZO), PEDOT, and metal nanowire, but the disclosure is not necessarily limited thereto. The first sensing conductive layer MT1 may form a connection electrode connecting sensing electrodes to each other.

The second insulating layer INS2 may be disposed on the first sensing conductive layer MT1. The second insulating layer INS2 and the first insulating layer INS1 may include a same material. In the alternative, second insulating layer INS2 may include at least one material selected from, e.g., the materials discussed herein with respect to the material constituting the first insulating layer INS1.

The second sensing conductive layer MT2 may be disposed on the second insulating layer INS2. The second sensing conductive layer MT2 may be partially opened not to overlap the light emitting element LD of each pixel PXL. In an example, the second sensing conductive layer MT2 may be disposed to overlap the non-emission area NEMA at the periphery of the emission area EMA.

The second sensing conductive layer MT2 and the first sensing conductive layer MT1 may include a same material. In the alternative, the second sensing conductive layer MT2 may include at least one material selected from, e.g., the materials discussed herein with respect to the material constituting the first sensing conductive layer MT1.

The second sensing conductive layer MT2 may be electrically connected to the first sensing conductive layer MT1 through a contact hole penetrating the second insulating layer INS2. The second sensing conductive layer MT2 may form sensing electrodes.

The third insulating layer INS3 may be disposed on the second sensing conductive layer MT2. The third insulating layer INS3 may include an organic layer, but the disclosure is not necessarily limited thereto. In some embodiments, the third insulating layer INS3 may be formed with an inorganic layer, or have a structure in which an organic layer and an inorganic layer are alternately stacked.

A light blocking layer LBP may be disposed on the display element layer DPL, the thin film encapsulation layer TFE, and/or the sensing layer TS. The light blocking layer LBP may include an opening overlapping the light emitting element LD of each pixel PX. In an example, the light blocking layer LBP may be disposed to overlap the non-emission area NEMA at the periphery of the emission area EMA.

The light blocking layer LBP may include a light blocking material to prevent light leakage and color mixture. In an example, the light blocking layer LBP may include a black matrix BM, but the disclosure is not necessarily limited thereto. In some embodiments, the light blocking layer LBP may include a carbon black (CB) and/or titan black (TiBK).

A color filter layer CFL may be disposed on the light blocking layer LBP. The color filter layer CFL may include color filters CF1, CF2, and CF3 which accord with colors of the respective pixels PXL. The color filters CF1, CF2, and CF3 which accord with the colors of the respective first to third pixels PXL1, PXL2, and PXL3 are disposed, so that a full-color image can be displayed.

The color filter layer CFL may include a first color filter CF1 disposed in the first pixel PXL1 to allow light emitted from the first pixel PXL1 to be selectively transmitted therethrough, a second color filter CF2 disposed in the second pixel PXL2 to allow light emitted from the second pixel PXL2 to be selectively transmitted therethrough, and a third color filter CF3 disposed in the third pixel PXL3 to allow light emitted from the third pixel PXL3 to be selectively transmitted therethrough.

In an embodiment, the first color filter CF1, the second color filter CF2, and the third color filter CF3 may be respectively a red color filter, a green color filter, and a blue color filter, but the disclosure is not necessarily limited thereto. Hereinafter, in case that an arbitrary color filter among the first color filter CF1, the second color filter CF2, and the third color filter CF3 is designated or in case that two or more kinds of color filters are inclusively designated, the corresponding color filter or the corresponding color filters are referred to as a “color filter CF” or “color filters CF.”

The first color filter CF1 may include a color filter material for allowing light of a first color (or red) to be selectively transmitted therethrough. For example, in case that the first pixel PXL1 is a red pixel, the first color filter CF1 may include a red color filter material.

The second color filter CF2 may include a color filter material for allowing light of a second color (or green) to be selectively transmitted therethrough. For example, in case that the second pixel PXL2 is a green pixel, the second color filter CF2 may include a green color filter material.

The third color filter CF3 may include a color filter material for allowing light of a third color (or blue) to be selectively transmitted therethrough. For example, in case that the third pixel PXL3 is a blue pixel, the third color filter CF3 may include a blue color filter material.

A window WD may be provided on the color filter layer CFL. The window WD may protect lower members from external impact, and provide an input surface and/or a display surface to a user.

In accordance with the above-described embodiment, adjacent layers of the light emitting element layer EML are formed of materials having different thermal expansion coefficients, thereby forming a crack CR inside the light emitting element layer EML. Thus, a current in the second area A2 in which the thickness of the light emitting element layer EML is non-uniform is blocked, thereby improving luminance uniformity.

Hereinafter, a method of manufacturing the display device in accordance with the above-described embodiment will be described.

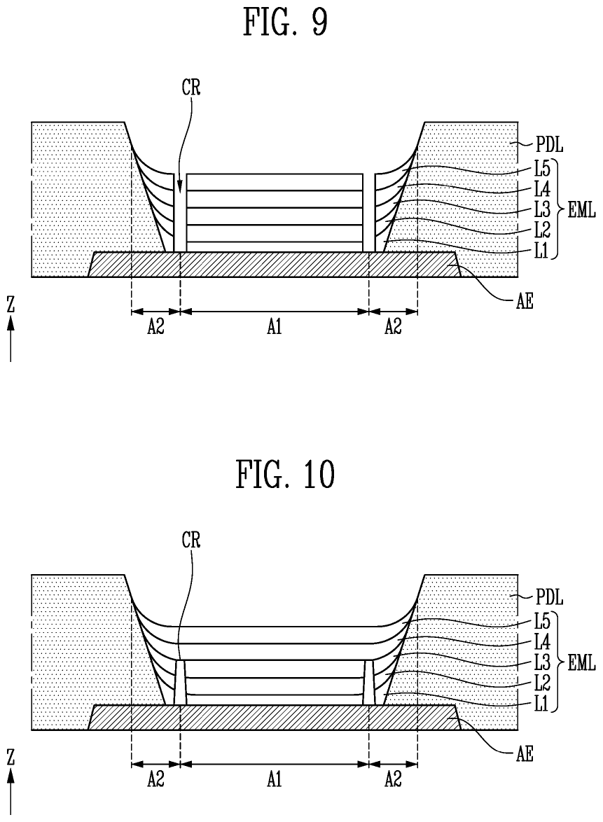

FIGS. 7 to 10 are schematic sectional views illustrating process steps of a method of manufacturing a display device in accordance with an embodiment of the disclosure. FIGS. 7 to 9 are sectional views illustrating a method of manufacturing the display device shown in FIG. 5, and FIG. 10 is a schematic sectional view illustrating a method of manufacturing the display device shown in FIG. 6. For convenience of discussion, components substantially the same as those described above are denoted by the same reference numerals, and detailed reference numerals are omitted.

Referring to FIG. 7, first, a first electrode AE is formed, and a bank PDL is formed over the first electrode AE. The bank PDL may include an opening partially exposing the first electrode AE. The bank PDL may cover an edge of the first electrode AE.

The bank PDL may be formed of an organic material. In an example, the bank PDL may be formed of acrylic resin, epoxy resin, phenolic resin, polyamide resin, polyimide resin, or the like, but the disclosure is not necessarily limited thereto.

In some embodiments, the bank PDL may be formed of a light absorption material, or have a light absorber applied thereon, to absorb light introduced from the outside. For example, the bank PDL may be formed of a carbon-based black pigment. However, the disclosure is not necessarily limited thereto, and the bank PDL may be formed of an opaque metal material such as chromium (Cr), molybdenum (Mo), an alloy (MoTi) of molybdenum and titanium, tungsten (W), vanadium (V), niobium (Nb), tantalum (Ta), manganese (Mn), cobalt (Co) or nickel (Ni), which has a high light absorption rate.

Referring to FIG. 8, subsequently, a light emitting element layer EML is formed on the first electrode AE. The light emitting element layer EML may be formed in the opening of the bank PDL. The light emitting element layer EML may be formed by inkjet printing, but the disclosure is not necessarily limited thereto. A thickness of the light emitting element layer EML may be partially non-uniformly formed in a process in which the light emitting element layer EML is printed in the opening of the bank PDL. In an example, a thickness t1 of a first area A1 of the light emitting element layer EML may be uniformly formed. The first area A1 of the light emitting clement layer EML may be located in the middle of the opening of the bank PDL. A thickness t2 of a second area A2 of the light emitting clement layer EML may be non-uniformly formed. The thickness t2 of the second area A2 of the light emitting element layer EML may be different from the thickness t1 of the first area A1 of the light emitting element layer EML. The thickness t2 of the second area A2 of the light emitting element layer EML may be thicker than the thickness t1 of the first area A1 of the light emitting element layer EML, but the disclosure is not necessarily limited thereto. The second area A2 of the light emitting element layer EML may be located at an edge of the opening of the bank PDL. The second area A2 of the light emitting element layer EML may surround the first area A1 of the light emitting element layer EML.

First to fifth layers L1, L2, L3, L4, and L5 of the light emitting element layer EML may be sequentially stacked on the first electrode AE. The first layer L1 may be formed on the first electrode AE and the bank PDL. The first layer L1 may be formed directly on the first electrode AE and the bank PDL. In an example, the first layer L1 may be a hole injection layer, but the disclosure is not necessarily limited thereto.

The second layer L2 may be formed on the first layer L1. The second layer L2 may be formed directly on the first layer L1. In an embodiment, a thermal expansion coefficient of the second layer L2 may be different from a thermal expansion coefficient of the first layer L1. In an example, the second layer L2 may be a hole transport layer, but the disclosure is not necessarily limited thereto.

The third layer L3 may be formed on the second layer L2. The third layer L3 may be formed directly on the second layer L2. In an embodiment, a thermal expansion coefficient of the third layer L3 may be different from the thermal expansion coefficient of the second layer L2. In an example, the third layer L3 may be a light emitting layer, but the disclosure is not necessarily limited thereto.

The fourth layer L4 may be formed on the third layer L3. The fourth layer L4 may be formed directly on the third layer L3. In an embodiment, a thermal expansion coefficient of the fourth layer L4 may be different from the thermal expansion coefficient of the third layer L3. In an example, the fourth layer L4 may be an electron transport layer, but the disclosure is not necessarily limited thereto.

The fifth layer L5 may be formed on the fourth layer LA. The fifth layer L5 may be formed directly on the fourth layer L4. In an embodiment, a thermal expansion coefficient of the fifth layer L5 may be different from the thermal expansion coefficient of the fourth layer L4. In an example, the fifth layer L5 may be an electron injection layer, but the disclosure is not necessarily limited thereto.

Although a case where the light emitting element layer EML includes the first to fifth layers L1, L2, L3, L4, and L5 is shown as an example in FIG. 8, the disclosure is not necessarily limited thereto. In an example, the light emitting element layer EML may additionally include layers include an electron blocking layer and/or a hole blocking layer.

Referring to FIGS. 9 and 10, subsequently, a crack CR is formed in the light emitting element layer EML by baking the light emitting element layer EML. As described above, in case that adjacent layers of the light emitting element layer EML are formed of materials having different thermal expansion coefficients, a crack CR may be formed inside the light emitting element layer EML due to thermal expansion in case that baking is performed at a high temperature. The crack CR of the light emitting element layer EML is formed between the first area A1 and the second area A2, to separate the first area A1 and the second area A2 from each other.

As shown in FIG. 9, the crack CR may entirely separate the first area A1 and the second area A2 of the light emitting element layer EML from each other. In an example, the crack CR may be formed in all the first to fifth layers L1, L2, L3, L4, and L5 to entirely separate the first area A1 and the second area A2 of the first to fifth layers L1, L2, L3, L4, and L5 from each other.

As shown in FIG. 10, the crack CR may partially separate the first area A1 and the second area A2 of the light emitting element layer EML from each other. In an example, the crack CR may be formed in some of the first to fifth layers L1, L2, L3, L4, and L5 to partially separate the first area A1 and the second area A2 of the first to fifth layers L1, L2, L3, L4, and L5 from each other. Although a case where a crack CR is partially formed in the first to third layers L1, L2, and L3 is shown as an example in FIG. 10, the disclosure is not necessarily limited thereto.

Subsequently, a second electrode CE is formed on the light emitting element layer EML, thereby completing the display device shown in FIG. 5 or 6.

In accordance with the above-described embodiment, adjacent layers of the light emitting element layer EML are formed of materials having different thermal expansion coefficients, thereby forming a crack CR inside the light emitting element layer EML. Thus, a current in the second area A2 in which the thickness of the light emitting element layer EML is non-uniform is blocked, thereby improving luminance uniformity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure and as set forth in the following claims.

What is claimed is:

1. A display device comprising:
a bank including an opening overlapping an emission area; and
a light emitting element layer disposed on the bank, wherein
the light emitting element layer includes a first area and a second area,
the first and second areas of the light emitting element layer are separated from each other in the opening, and
a thickness of the first area is different from a thickness of the second area.

2. The display device of claim 1, wherein the second area surrounds the first area.

3. The display device of claim 1, wherein the first area is disposed in a middle of the opening.

4. The display device of claim 1, wherein the second area is in contact with the bank.

5. The display device of claim 1, wherein the first area has uniform thicknesses.

6. The display device of claim 1, wherein the second area has non-uniform thicknesses.

7. The display device of claim 1, wherein
the light emitting element layer includes a first layer disposed on the bank and a second layer disposed on the first layer, and
a thermal expansion coefficient of the first layer is different from a thermal expansion coefficient of the second layer.

8. The display device of claim 7, wherein the second layer is disposed directly on the first layer.

9. The display device of claim 7, wherein
the light emitting element layer further includes a third layer disposed on the second layer, and
a thermal expansion coefficient of the third layer is different from the thermal expansion coefficient of the second layer.

10. The display device of claim 9, wherein the third layer is disposed directly on the second layer.

11. A method of manufacturing a display device, the method comprising:
forming a bank including an opening over a first electrode;
forming a light emitting element layer in the opening;
forming a crack in the light emitting element layer by baking the light emitting element layer; and
forming a second electrode on the light emitting element layer.

12. The method of claim 11, wherein the light emitting element layer includes a first area and a second area which have different thicknesses from each other.

13. The method of claim 12, wherein the crack separates the first area and the second area from each other.

14. The method of claim 12, wherein the first area has uniform thicknesses.

15. The method of claim 14, wherein the first area is formed in a middle of the opening.

16. The method of claim 12, wherein the second area has non-uniform thicknesses.

17. The method of claim 12, wherein the second area surrounds the first area.

18. The method of claim 11, wherein the forming of the light emitting element layer includes forming a first layer on the first electrode and forming a second layer on the first layer.

19. The method of claim 18, wherein a thermal expansion coefficient of the first layer is different from a thermal expansion coefficient of the second layer.

20. The method of claim 19, wherein
the forming of the light emitting element layer further includes forming a third layer on the second layer, and
a thermal expansion coefficient of the third layer is different from the thermal expansion coefficient of the second layer.
